(19) United States
(12) Patent Application Publication
(10) Pub. No.: US 2006/0038581 A1
(43) Pub. Date: Feb. 23, 2006

(54) Display panel inspection apparatus and display panel inspection method

(75) Inventor: Mikio Kanai, Saitama-ken (JP)

Correspondence Address: ARENT FOX PLLC, 1050 CONNECTICUT AVENUE, N.W., SUITE 400, WASHINGTON, DC, 20036, US

(73) Assignees: PIONEER CORPORATION; PIONEER FA CORPORATION

(21) Appl. No.: 11/201,425

(22) Filed: Aug. 11, 2005

(30) Foreign Application Priority Data
Aug. 18, 2004 (JP) 2004-238697

(51) Int. Cl. G01R 31/00

(52) U.S. Cl. 324/770

(57) ABSTRACT

It is an object of the present invention to provide a display panel inspection apparatus and an inspection method capable of remarkably reducing equipment cost and shortening inspection time. The apparatus comprises: an image measurement unit which lights a display panel (work) in response to a test signal and pick up an image of the lighted display panel, thereby obtaining image measurement data; a data accumulating unit for accumulating the image measurement data of a plurality of display panels as data corresponding to the respective display panels; and a data processing unit which respectively reads out the image measurement data accumulated in the data accumulating unit and performs image processing so as to judge the quality of each display panel. When inspecting a plurality of display panels, the image measurement unit and the data processing unit perform inspections independently. The image measurement unit operates to output identification data for identifying the respective display panels acting as measurement objects and image measurement data to the data accumulating unit, while the data accumulating unit forms a data base for managing the identification data and the image measurement data corresponding to the identification data.

### BACKGROUND OF THE INVENTION

The present invention relates to a display panel inspection apparatus and a display panel inspection method.

The present application claims priority from Japanese Application No. 2004-238697, the disclosure of which is incorporated herein by reference.

A display panel such as a plasma display panel, a liquid crystal display panel, and an organic EL (Electroluminescence) panel, upon having been formed as a display panel, is usually subjected to various inspections to check its brightness uniformity with respect to white light emission, its luminescent spot with respect to black color display, its color un-uniformity, its pixel defect and its margin test (an amount of luminescence with respect to an amount of input signal), thereby effecting a quality management on completed products based on the results of such inspections.

A display panel inspection apparatus used at this time, as shown in FIG. 1, has an inspection table J2 on which a display panel J1 is mounted. Disposed on the left and right sides of the inspection table J2 are an un-loader for removing an inspected display panel J1 from the inspection table J2 and a loader J4 for moving an un-inspected display panel J1 to the inspection table J2. Further, a prober (a lighting circuit) J5 is provided on one side of the inspection table J2 and connected to a terminal of the display panel J1 so as to light the display panel J1. Beside, disposed above the display panel J1 is a CCD camera J6 which is connected with a data processing unit J7. In fact, such a display panel inspection apparatus is formed by installing all necessary units in an integral structure serving as a measurement apparatus, but not including the display panel J1. Here, the data processing unit J7 includes an A/D converter J71, a computing circuit J72, an image memory J73, and a displaying circuit J74.

When using the above-described display panel inspection apparatus to perform an inspection, a display panel J1 is supplied to the inspection table J2 from the loader J4 and set at a predetermined position. Then, the prober J5 is connected to the display panel J1 and a lighting signal is thus supplied thereto. Subsequently, the CCD camera J6 located above the display panel J1 operates to pick up the image of an entire display area of the display panel J6, while a lighting brightness of the display panel is fed as a video signal to the data processing unit J7. Here, the data processing unit J7 operates to digitalize the video signal fed thereto and accumulates the same as gradient indication data in an image memory J73. Afterwards, the data stored in the image memory J73 is read out to perform an inspection based on the measured values. This prior art is disclosed in Japanese Unexamined Patent Application Publication Hei No. 6-222315.

However, during an inspection performed by the above-described conventional display panel inspection apparatus, a high miniaturization and a large size screen of a display panel will bring about an existence of a large amount of measurement information. On the other hand, as mentioned above, since there are many inspection items such as brightness uniformity, luminescent spot, color un-uniformity, pixel defect and margin test, a considerable amount of time is needed for the data processing unit to process image measurement data obtained by the CCD camera. Then, the display panel, after having been set in the display panel inspection apparatus, is placed in a stand-by state in which it stays on an inspection table, and such a stand-by state continues until the data processing based on the data processing unit is ended and the quality determination is performed to determine whether product quality is acceptable. As a result, the above process greatly affects the tact time of the display panel inspection apparatus, making it impossible to perform an inspection with a high productivity.

Moreover, in order to meet a requirement in production time in manufacturing display panel and realizing an inspection line using the above-described display panel inspection apparatus, it is necessary to introduce a plurality of such display panel inspection apparatus, thus resulting in an increased cost of equipment investment because an enlarged setting space is needed and unit price of each inspection apparatus is high. Furthermore, during the progress of panel production, if the production plan or the like has to be changed and the changed plan or the like fails to satisfy a required production time, it is necessary to further increase the number of sets of display panel inspection apparatus, thus making it impossible to avoid an increased equipment cost because it is necessary to perform further setting-up of apparatus, obtain further setting space and pay the prices for further apparatus. As a result, it is impossible to obtain a desired freedom in production adjustment.

Besides, if it is necessary to employ a plurality of display panel inspection apparatuses, a troublesome adjustment has to be performed in obtaining image measurement data, and measurement results are likely to be somehow different from one apparatus to another, thus making it difficult to manage a quality control.

### SUMMARY OF THE INVENTION

The present invention has been accomplished in order to solve the foregoing problem, and it is an object of the invention to realize an improved inspection within a reduced space, at a low cost and a high productivity, and when such a high productivity is to be ensured, to alleviate an adjustment in obtaining image measurement data, to eliminate a measurement un-uniformity caused due to apparatus differences, thereby ensuring an acceptable quality management.

To achieve the foregoing objects, a display panel Inspection apparatus and a display panel Inspection method according to the present invention, have at least the following features in the following aspects.

According to one aspect of the present invention, there is provided a display panel inspection apparatus comprising: at least one image measurement unit which lights a display panel in response to a test signal and picks up the image of the lighted display panel so as to obtain image measurement data; at least one data accumulating unit for accumulating the image measurement data of a plurality of display panels as data corresponding to each display panel; and at least one data processing unit which respectively reads out the image measurement data accumulated in the data accumulating unit and performs image processing so as to judge the quality of each display panel. In particular, when inspecting a plurality of display panels, the at least one image measurement unit and the at least one data processing unit perform inspections independently.

According to another aspect of the present invention, there is provided a display panel inspection method using a display panel inspection apparatus comprising: at least one image measurement unit which lights a display panel in response to a test signal and picks up the image of the lighted display panel so as to obtain image measurement data; at least one data accumulating unit for accumulating the image measurement data of a plurality of display panels as data corresponding to each display panel; and at least one data processing unit which respectively reads out the image measurement data accumulated in the data accumulating unit and performs image processing so as to judge the quality of each display panel. This method comprises: an image measurement step of supplying display panel acting as measurement object to the at least one image measurement unit, outputting the image measurement data to the at least one data accumulating unit, discharging a measured display panel and supplying a next display panel acting as a measurement object; and a data processing step of sorting said image measurement data outputted from the at least one data accumulating unit and corresponding to each display panel to a plurality of data processing units in their stand-by state, and performing said image processing.

### BRIEF DESCRIPTION OF THE DRAWINGS

These and other objects and advantages of the present invention will become clear from the following description with reference to the accompanying drawings, wherein:

FIG. 1 is an explanatory view showing a conventional display panel inspection apparatus;

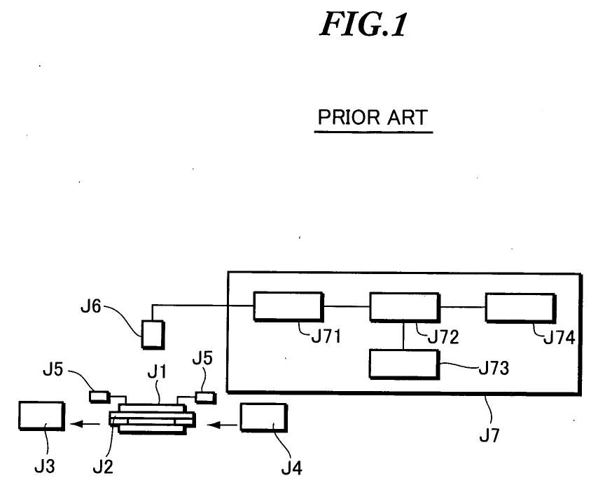

FIG. 2 is an explanatory view showing a display panel inspection apparatus and an inspection method according to an embodiment of the present invention;

FIG. 3 is an explanatory view showing a display panel inspection apparatus and an inspection method according to another embodiment of the present invention;

FIG. 4 is a flow chart showing various steps required in processing one piece of work according to an embodiment of the present invention; and

FIG. 5 is an explanatory view showing a comparison between an inspection according to an embodiment of the present invention and another inspection according to a prior art.

### DETAILED DESCRIPTION OF THE PREFERRED EMBODIMENTS

In the following, description will be given in detail to explain a display panel Inspection apparatus and a display panel Inspection method according to the present invention, with reference to the accompanying drawings.

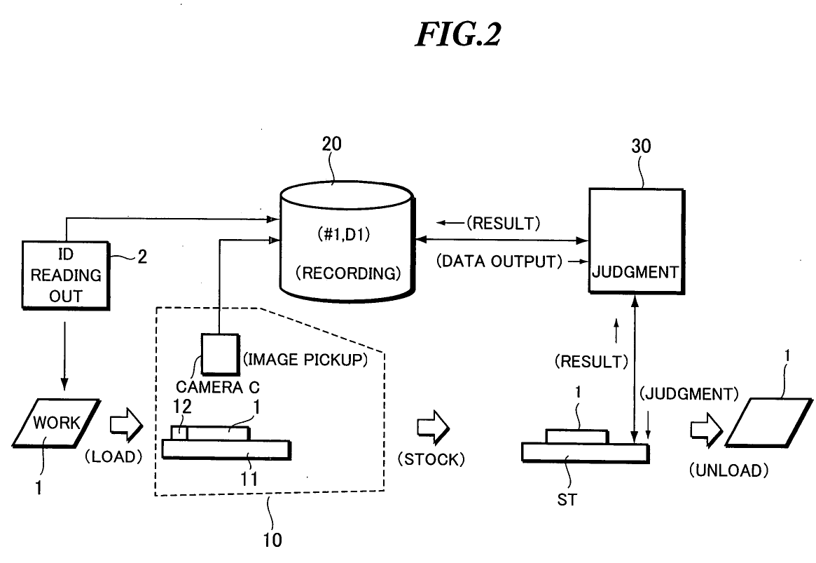

FIG. 2 is an explanatory conceptual view showing an example of a whole process for carrying out display panel inspection using a display panel inspection apparatus formed according to an embodiment of the present invention. Here, in the present embodiment of the present invention, a display panel (hereinafter, referred to as “work”) to be inspected can be an LCD (Liquid Crystal Display), a PDP (Plasma Display Panel), an organic EL (Electroluminescence) panel and the like.

An inspection apparatus according to the present embodiment of the present invention comprises: an image measurement unit 10 for lighting a display panel in response to a test signal and pick up the lighted image so as to obtain image measurement data; a data accumulating unit 20 capable of accumulating the obtained image measurement data of a plurality of display panels as data corresponding to each display panel; a data processing unit 30 for reading out various image measurement data accumulated in the data accumulating unit 20 and then image-processing the read-out data so as to judge the quality of each display panel. When a plurality of display panels are being inspected, the image measurement unit 10 and the data processing unit 30 will operate independently.

To describe in more detail, as shown in FIG. 2, in an image measurement step serving as a first step, an ID reader 2 operates to identify an ID number described in a display panel 1 (hereinafter, referred to as work 1), and then the work 1 is loaded on to the image measurement unit 10. In the image measurement unit 10, the work 1 is mounted on an inspection table 11, while a contact head 12 gets in contact with the work 1 in a manner such that the work 1 can be lighted in response to a test signal. Subsequently, the work 1 is lighted in response to the test signal, and a lighted image is picked up by an image processing camera such as CCD camera.

Inspection items based on the test signal mainly include: a quality judgment concerning a brightness un-uniformity with respect to a whit light emission; a quality judgment concerning lacking of pixels; a quality judgment concerning luminescent spot with respect to black color display; a quality judgment concerning a color un-uniformity with respect to RBG (Red, Blue, Green) displays; and a margin test (luminescence test with respect to an applied voltage). Once image pickup using camera is completed for all the inspection items, the image measurement unit 10 detects an end of a process of obtaining image measurement data with respect to the work 1 set there in position, and outputs a discharge signal. Afterwards, the work 1 is temporarily stocked on a stocker ST and placed in a stand-by state.

Next, in data recording step, the obtained image measurement data is handled as data corresponding to each work 1 and digitalized by an A/D converter, and then recorded in the data accumulating unit 20 capable of accumulating an amount of data relating to a plurality of display panels. At this time, along with the individual ID numbers identified by the ID reader 2, the respective data are recorded correspondingly. In FIG. 2, the data of the work 1 is indicated as (#1, D1), while the data accumulating unit 20 indicates that the image measurement data D1 is recorded corresponding to ID number #1.

Subsequently, in data processing step, when the work 1 is stocked on the stocker ST, the image measurement data D1 and ID number #1 are outputted from the data accumulating unit 20. Then, the data processing unit 30 operates to perform a quality judgment to determine whether the work 1 acting as an inspection object is acceptable as a good product. As a result, the judgment (to judge whether the work 1 is acceptable) result of the work 1 is again recorded along with the ID number #1 in the data accumulating unit 20. Then, the work 1 stocked on the stocker ST, in accordance with a display panel discharge signal based on the data processing unit 30, is unloaded and discharged from a series of inspection devices.

Here, the present embodiment of the present invention involves a panel supply device (which is a loader, but not shown in FIG. 2) for supplying display panels (works) acting as measurement objects to the image measurement unit 10, and a panel stock device (stocker ST) for stocking a display panel discharged from the image measurement unit 10 and completed in its measurement. Here, the image measurement unit 10 detects an end of a process of obtaining image measurement data with respect to a display panel (work) set in position, outputs a display panel discharge signal, and temporarily stocks the display panel (work) on the stocker ST. From this onwards, the same image measurement, data recording and data processing are performed successively on other works until work N. Then, the data accumulating unit 20 accumulates ID numbers, image measurement data, and quality judgment results or the like with respect to a plurality of display panels (works).

Moreover, the image measurement unit 10 detects that a measured display panel (work) has been discharged and outputs a display panel supply signal to the panel supply device (loader). Specifically, the image measurement unit 10 performs an image-pickup on the image measurement data of the work 1 by virtue of a camera C, and upon completing all inspection items, issues a commend for a next work (work 2) to be supplied from the loader. Namely, the image measurement unit 10, upon completing an image-pickup on the work 1, discharges the work 1 to the stocker ST, loads a next work (work 2), and prepares to start an inspection on the work 2. Subsequently, similar to a step of processing the work 1, image measurement data based on image pickup is obtained with respect to the work 2, followed by performing the same operation on other works.

In this way, according to an embodiment shown in FIG. 2, when a plurality of continuously connected works are being inspected, the image measurement unit 10 and the data processing unit 30 can independently conduct inspection process, so that the image measurement unit 10 and the data processing unit 30 can measure different works and process data within a shortened time. As a result, it is possible to make full use of the display panel inspection apparatus without being affected by the tact time of the apparatus itself, thereby ensuring an efficient inspection.

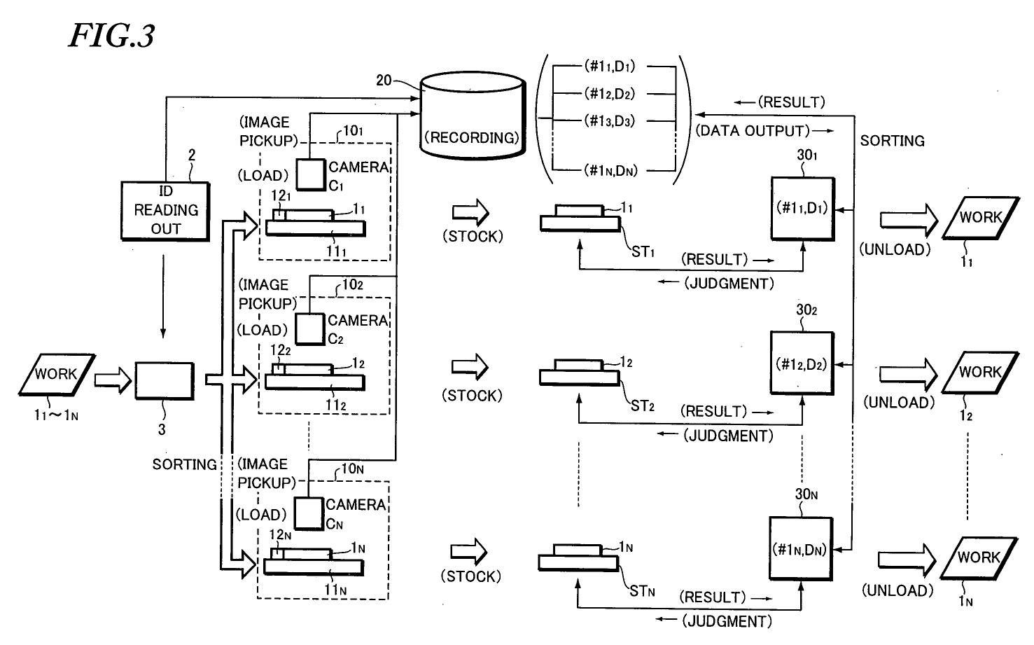

Next, with reference to FIG. 3, description will be given in detail to explain another display panel inspection apparatus according to another embodiment of the present invention. However, the same description will be omitted as to those contents which are the same as the embodiment shown in FIG. 2. As shown in FIG. 3, the display panel inspection apparatus of this embodiment comprises a plurality of image measurement units 10 (image measurement units 10₁ to 10_{N}), and the equal number of data processing units 30 (data processing units 30₁ to 30_{N}). Various elements forming the apparatus of the present embodiment will be described in detail below.

As shown, the respective works 1₁ to 1_{N} having passed through a series of manufacturing steps are set from upstream to a sorting conveyor 3, and their ID numbers (serving as identification numbers) printed in advance on work main bodies are identified by the ID reader 2. On the other hand, it is also possible to at first identify the ID numbers and then set these works on the sorting conveyor 3. Subsequently, the sorting conveyer 3 operates to select an image measurement unit (which starts inspection earlier than other image measurement units) from a plurality of image measurement units 10 (FIG. 3 shows an example involving N image measurement units 10₁ to 10_{N}), and successively set the works 1₁ to 1_{N} in this inspection apparatus. Here, FIG. 3 shows an example in which the works 1₁ to 1_{N} are respectively mounted on the respective inspection tables 11₁ to 11_{N} of the image measurement units 10₁ to 10_{N}, with contact heads 12₁ to 12_{N} being in contact with the respective works 1₁ to 1_{N}. However, it is also possible for the total number N of the works 1₁ to 1_{N} to be unequal to the total number N of the image measurement units 10₁ to 10_{N}.

An inspection process based on an embodiment shown in FIG. 3 will be described in detail below. Namely, at first, in an image measurement step, the respective image measurement units 10₁ to 10_{N} use image processing cameras C₁ to C_{N} such as CCD camera to collect the image measurement data D₁ to D_{N} of the respective works 1₁ to 1_{N}. The inspection items involved in the present embodiment are just the same as the embodiment shown in FIG. 2, including: a quality judgment concerning a brightness un-uniformity with respect to a whit light emission; a quality judgment concerning lacking of pixels; a quality judgment concerning luminescent spot with respect to black color display; a quality judgment concerning a color un-uniformity with respect to RBG (Red, Blue, Green) displays; and a margin test (luminescence test with respect to an applied voltage). Once image pickup using camera is completed for all the inspection items, the image measurement units 10₁ to 10_{N} will output display panel discharge signals, so that the measured works 11 to 1N will be stocked on the corresponding stockers ST₁ to ST_{N} and placed in a stand-by state.

Next, in a data recording step, image measurement data D₁ to D_{N} of the respective works 1₁ to 1_{N}, together with the ID numbers printed in advance on the respective works 1₁ to 1_{N}, are recorded in the data accumulating unit 20. In FIG. 3, signs (#1₁, D₁) to (#1_{N}, D_{N}) represent that data accumulating unit 20 has recorded the respective image measurement data D₁ to D_{N} corresponding to the ID numbers #1₁ to #1_{N}. Here, in order to record all these data, it is preferable that the data accumulating unit 20 be formed of a hard disc having a large capacity for backup storage, thereby forming a data base.

Next, in a data processing step, the data processing units 30₁ to 30_{N} output image measurement data (obtained from the data accumulating unit 20) of the respective works 1₁ to 1_{N} so that these data are respectively fed into the corresponding data processing units 30₁ to 30_{N}, thereby performing quality judgment based on the inspections of the foregoing items, and then issuing discharge commends to the works staying on the stockers ST₁ to ST_{N}. Subsequently, the corresponding works are discharged and moved to the next step. Namely, the quality judgment results based on the plurality of data processing units 30₁ to 30_{N}, together with the ID numbers, are additionally recorded in the data accumulating unit 20, while the respective works 1₁ to 1_{N} stocked on the respective stockers ST₁ to ST_{N} are unloaded and thus discharged from a series of inspection devices.

The present embodiment involves a plurality of image measurement units 10₁ to 10_{N} and the equal number of data processing units 30₁ to 30_{N} corresponding to the image measurement units 10₁ to 10_{N}. However, in the present invention, there should not be any limitation to the number of the image measurement units and the data processing units. Namely, the number of data processing units can be decided in accordance with a processing time necessary for carrying out the data processing step. For example, it is possible to set two data processing units with respect to one image measurement unit. At this time, during stand-by, the data accumulating unit 20 operates to respectively send image measurement data corresponding to the respective display panels to the plurality of data processing units 30₁ to 30_{N} and then output the same. On the other hand, if necessary, it is also possible to set a plurality of such data accumulating units 20.

According to the present embodiment, each image measurement unit 10 carries out an image measurement step based on image picking-up and a data recording step, and when a work 1 is stocked on a stocker ST, the each image measurement unit 10 carries out a data processing step for work 1. Meanwhile, a next (another) work is set in the same image measurement unit so as to carry out the same image measurement and data recording. Namely, in the present embodiment, it is possible to realize a parallel treatment simultaneously including an image measurement step and a data processing step, thereby ensuring an efficient inspection.

Moreover, according to the present embodiment, the image measurement data and inspection results of the respective works 1₁ to 1_{N} are recorded in the data accumulating unit 20 during a data recording step, thereby forming a data base and thus obtaining an effect of easily reproducing desired products. In more detail, it is possible to effect a feed-back in a work manufacturing process, improve the manufacturing process to reduce some reasons responsible for defect products, thereby increasing the yield of final products. Further, even for acceptable products which have already been put into market, it is possible to easily perform a product quality management involving works (display panels) by virtue of ID numbers.

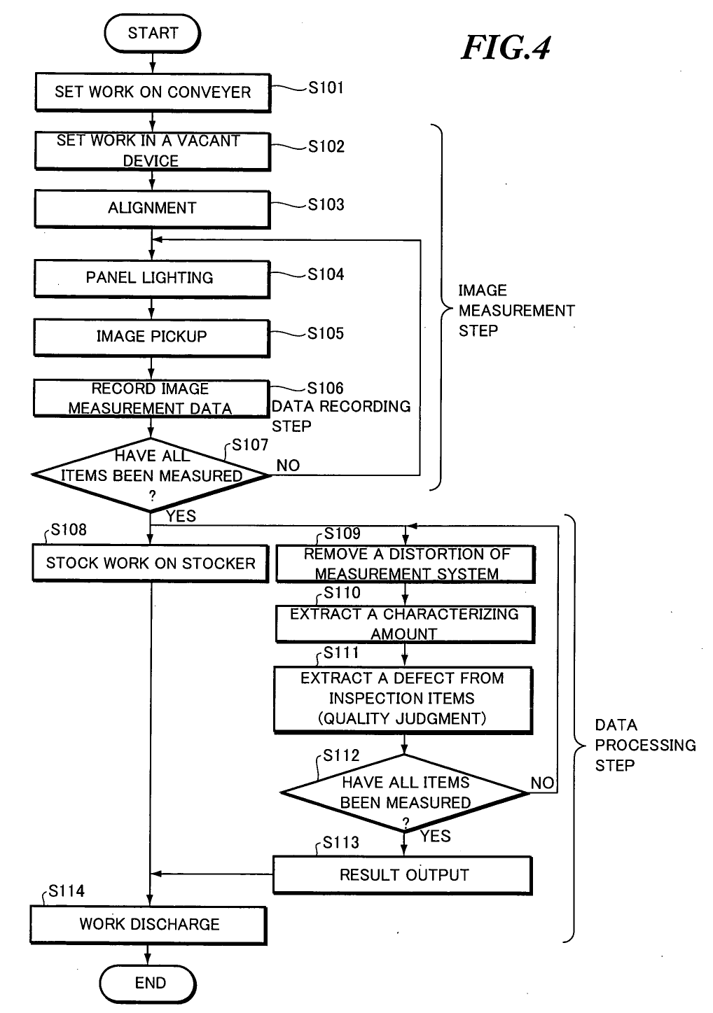

FIG. 4 is a flow chart showing a procedure (including steps S101 to S114) in which a work 1 passes through an image measurement step, a data recording step and a data processing step before being discharged outside. In the following, description will be given in detail with reference to the flow chart, with the image measurement step corresponding to S101-S105, the data recording step corresponding to S106, and the data processing step corresponding to S109-S113.

At first, a work 1 is set on the sorting conveyor 3 and its ID number is identified by the ID reader 2 (S101). Then, a vacant unit is selected from the image measurement units 10₁ to 10_{N} so as to set the work 1 thereon (S102). Next, the work 1 is aligned so as to be located at a predetermined position (S103), and pressed towards the contact head 12, so that the display panel is lighted and a test signal generator is used to indicate the lighting of an inspection pattern based on a test signal in comply with an inspection item (S104) Afterwards, a highly precision camera (for example, CCD camera) is used to pick up the image of an inspection image of the panel (S105).

Here, the digitalized image measurement data and the ID number of the work 1 are stored in the data accumulating unit 20 (S106, data recording step). Further, when a measurement is carried out in relation to other inspection item, the process returns to S104, thereby lighting an inspection pattern based on a test signal in comply with an inspection item and thus performing image-pickup. The picked-up image and an ID number are recorded and thus stored in the data accumulating unit 20. Then, with respect to all the inspection items, data are recorded and stored so that the image measurement step (S101 to S105, S107) is completed and the contact head 12 is released.

Afterwards, the work 1 is stocked on the stocker ST₁ (S108) Meanwhile, the image measurement data of the work 1 recorded and stored in the data accumulating unit 20 is transferred to a data processing step and processed by the data processing unit 30 containing a high speed computation processing device. By virtue of such a high speed computation processing device, an image reading is initially performed and a distortion of the measurement system is deleted (S109). Then, after extracting a characterizing amount (S110), a defect is extracted and at the same time a quality judgment is carried out corresponding to inspection items in accordance with the magnitude of the characterizing amount (S111).

Then, if there remain other items which have not yet been inspected, the process will return to S109, so as to delete a distortion of the measurement system, extract a characterizing amount, extract a defect, and judge an inspection quality, with respect to all the inspection items (S109 to S111).

When an inspection value obtained through the extraction of defect (S111) is within an appropriate range, a work is determined to be an appropriate one, but will be determined to be an inappropriate one if the inspection value is not within the appropriate range. The information as to whether a work is acceptable or not and the ID number thereof are recorded and thus stored in the data accumulating unit 20, followed by outputting the results of all inspection items (S113). Then, with respect to the stocker ST₁ on which a work 1 has been stocked, the data processing unit 30₁ issues a commend for discharging the work 1, so that the work 1 is discharged (S114) In this way, a series of image measurement step, data recording step and data processing step are thus completed.

However, after the work 1 is stocked on the stocker ST₁ (S108), a next work waiting on the sorting conveyer 3 will be set into the image measurement unit 101 at S102, thereby starting another image measurement step on the next work in the same manner as described above.

In this way, after an image measurement step has been carried out to process one piece of work, it is allowed to carry out another image measurement step to process a next work while at the same time carrying out a data processing step, thereby making it possible to reduce a total amount of inspection time. However, in the above-described prior art, it was impossible to process a next work until an initial work is completed in all processing steps. In contrast with the prior art, the present embodiment of the present invention makes it possible to remarkably shorten a total amount of inspection time.

Moreover, since the data processing step is carried out by a data processing unit capable of performing a high speed computation, the present invention provides an inspection different from a conventional inspection which is conducted only by man's naked eyes like monitor checking. In this way, it is possible to greatly reduce the number of human beings in charge of the inspection, as compared to the prior art.

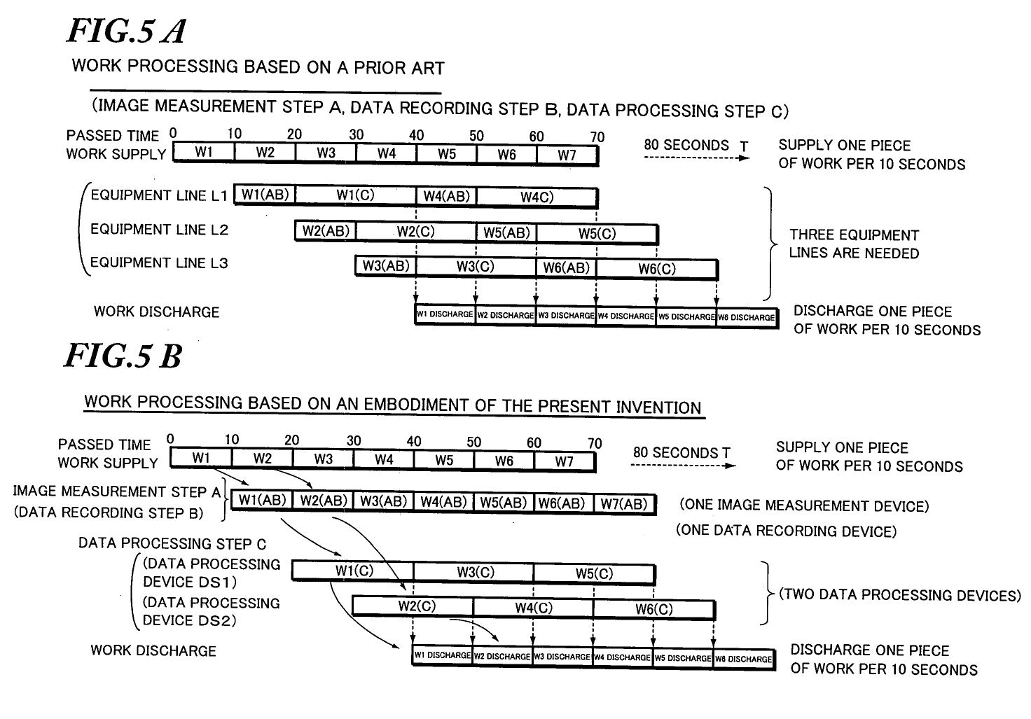

Next, with reference to FIG. 5, a comparison will be made between an inspection process according to an embodiment of the present invention and an inspection process according to a prior art. In more detail, FIG. 5A shows a work (display panel) processing according to a prior art, and FIG. 5B shows a work (display panel) processing by using a display panel inspection apparatus and a display panel inspection method according to the embodiments of the present invention. In fact, these drawings show an image measurement step A, a data recording step B, and a data processing step C.

In order to carry out an easy comparison between a conventional work processing (shown in FIG. 5A) and a work processing according to an embodiment of the present invention (shown in FIG. 5B), the conventional work processing (shown in FIG. 5A) is shown in a manner such that one equipment line (such as equipment line L1) processes one work by continuously passing the same through an image measurement step A, a data recording step D, and a data processing step C. After the data processing step C has been completed, a next work will be supplied to the inspection system. Then, as an inspection condition used and shown in FIG. 5A and FIG. 5B, a work supply cycle for one work to be supplied from an upstream is 10 seconds/sheet. Further, a time period for processing a work on the sorting conveyer 3 is 10 seconds/sheet, while the time for other processings is 30 seconds/sheet (the image measurement step A including the data recording step B is 10 seconds/sheet, and the data processing step C is 20 seconds/sheet).

Next, description will be given to explain the conventional work processings shown in FIG. 5A. Practically, these processings make use of conventional equipment lines L1, L2, and L3, while each work is supplied at a rate of 10 seconds/sheet. Actually, FIG. 5A shows that works are supplied in the order of equipment lines L1, L2, and L3. With respect to the equipment line L1, a work W1 supplied at a time of T=0 is set in a predetermined position at a time of T=10, and during a next 10 seconds until T=20, the image measurement step A and the data recording step B are carried out so as to perform an image measurement and a data recording. Then, during a next 20 seconds from T=20 to T=4, an image processing is performed through the data processing step C. Subsequently, at a time of T=40, the work is discharged from the equipment L1 and a next work W4 from an upstream is set at a predetermined position on the equipment line L1, thereby receiving the same processing. In addition, other equipment lines L2 and L3 perform the same processings as described above.

In this way, as shown in FIG. 5A, the work discharge rate is 10 seconds/sheet, so that during a time period from T=0 (when work W1 is supplied) to T=70, four pieces of works (works W1 to W4) are discharged, and the equipment lines L1, L2, and L3 are needed in processing these works as described above.

Next, description will be given to explain an inspection method using the display panel inspection apparatus according to an embodiment of the present invention. Here, in order to obtain the same effect as in the work processing shown in FIG. 5A (three works are discharged during T=0-70), the embodiment of the present invention is such that the image measurement step A employs one image measurement unit, the data recording step B employs one hard disc having a large capacity, and the data processing step C employs two data processing units DS1 and DS2. Namely, according to the embodiment of the present invention, the number of the image measurement units 10 and the data processing units 30 is decided in response to the length of processing time in each device.

In more detail, the work W1 supplied at T=0 is set at a predetermined position in the image measurement unit 10 by virtue of the sorting conveyer 3. Then, during T=10-20, an image measurement processing and data recording are performed in the image measurement step A and the data recording step B. Further, at T=20, the image measurement data of the work W1 having passed through the image measurement step A and waiting on the stocker ST₁ is transferred to the data processing step C in the data processing unit DS1. In the data processing unit DS1, image processing and recording are performed during a time period of T=20-40. Subsequently, at T=40, the work W1 is discharged from the stocker ST₁.

Then, once the work 1 is set in the inspection system (T=20), a work 2 supplied from the upstream is processed in the same image measurement unit 10 so as to carry out the image measurement step A and the data recording step B. At T=30, the work W2 is caused to wait on the stocker ST₂, while the related image measurement data is fed to another data processing unit DS2 and then transferred to the data processing step C. 20 seconds later at T=50, the work W2 is discharged from the stocker ST₂. As to the works from the work W3 onwards, the same processing as that described above will be carried out.

Therefore, as shown in FIG. 5B, if it is required to discharge three pieces of works W1, W2, and W3 during T=0-70 which has the same contents as the work processing results shown in FIG. 5A, the present embodiment of the present invention only requires using one image measurement unit 10, one data accumulating unit 20, and two data processing units DS1, DS2. In fact, since the data processing units DS1, DS2 are used mainly for performing a quality judgment based on the inspection, they can be in the form of computers or the like.

In this way, as shown in FIG. 5B, since the data recording step B and the data processing step C can be completed simply by using a hard disc having a large capacity and a data processing device capable of performing a high speed computation (for example, a personal computer), it is possible to reduce the equipment cost.

Namely, it is possible to avoid an expensive equipment cost even if the above-described apparatuses are replaced by new ones. On the other hand, even if it is necessary to increase equipment, the number of sets of necessary equipment can be decided in view of a processing time of each apparatus, so that a necessary operation is only to introduce any one of an inspection device for carrying out an image measurement step, a recording device for carrying out a data recording step, and a data processing device for carrying out a data processing step, thereby making it possible to increase equipment with only a minimum introduction expense and a lowest equipment cost.

In fact, what operates as an inspection line requires only one image measurement unit 10 for carrying out an image measurement step, thus making it possible to save an equipment setting space and thus remarkably reduce equipment cost as compared to prior art.

Moreover, according to the above-describe embodiment of the present invention, after inspection data is collected in an image measurement step, a work is stocked on a stocker, with only inspection data being processed separately in a data processing step. Meanwhile, a next work is processed by carrying out a similar image measurement step. Accordingly, inspection can be realized by constantly and independently carrying out an image measurement step and a data processing step. In particular, when both of the image measurement step and the data processing step are carried out in parallel, it is possible to reduce a time period necessary for one piece of work to be mounted in an inspection apparatus, thereby ensuring an efficient inspection for inspecting display panel.

As explained above, the display panel inspection apparatus and the inspection method according to the above-described embodiment of the present invention, make it possible to perform inspection by independently carrying out an image measurement step and a data processing step together functioning as an inspection line in an inspection process. As a result, it is possible to carry out the image measurement step and the data processing step in parallel, thereby improving productivity.

Moreover, by setting the number of the data processing units for carrying out the data processing step in accordance with a processing time of the data processing step, it is allowed to reduce the number of the inspection devices to be used, to simplify an adjustment which is to be performed in obtaining image measurement data and can be seen when employing a plurality of inspection apparatuses. In this way, it is possible to reduce a possibility of producing an irregularity (an aberration or the like) in measurement results, which is possibly caused due to differences among a plurality of inspection apparatus, thereby making it possible to ensure an acceptable quality management.

In addition, since an inspection data collection and a quality judgment based on an inspection can be separated from each other and carried out in parallel, it is possible to remarkably reduce an inspection time in handling each piece of work, save an operational space and thus reduce an equipment cost, thereby making it possible to inhibit in advance an increase in equipment investment. Then, even with regard to a situation indicating that it is difficult to predict a change in production plan during a progress of panel production, it is allowed to increase necessary devices such as image measurement device, data storage device, and data processing device. Therefore, it is possible to effectively use existing apparatus, and flexibly deal with a change in production plan.

While there has been described what are at present considered to be preferred embodiments of the present invention, it will be understood that various modifications may be made thereto, and it is intended that the appended claims cover all such modifications as fall within the true spirit and scope of the invention.

1. A display panel inspection apparatus comprising:
at least one image measurement unit which lights a display panel in response to a test signal and picks up the image of the lighted display panel so as to obtain image measurement data;
at least one data accumulating unit for accumulating the image measurement data of a plurality of display panels as data corresponding to each display panel; and
at least one data processing unit which respectively reads out the image measurement data accumulated in the data accumulating unit and performs image processing so as to judge the quality of each display panel,
wherein when inspecting a plurality of display panels, the at least one image measurement unit and the at least one data processing unit perform inspections independently.

2. The display panel inspection apparatus according to claim 1, wherein
the at least one image measurement unit operates to output identification data for identifying the respective display panels acting as measurement objects and image measurement data to the at least one data accumulating unit,
the at least one data accumulating unit forms a data base for managing the identification data and the image measurement data corresponding to the identification data.

3. The display panel inspection apparatus according to claim 1, further comprising panel supply means for supplying display panel acting as measurement object to the at least one image measurement unit, and panel stocking means for stocking measured display panel discharged from the at least one image measurement unit,
wherein the image measurement unit detects an end of a process of obtaining image measurement data with respect to a display panel set in a predetermined position, and outputs a display panel discharge signal.

4. The display panel inspection apparatus according to claim 3, wherein the image measurement unit detects that a measured display panel has been discharged and outputs a display panel supply signal to the panel supply means.

5. The display panel inspection apparatus according to claim 1,
wherein said apparatus comprises a plurality of data processing units,
wherein the at least one data accumulating unit operates to sort image measurement data corresponding to each display panel to the plurality of data processing units in their stand-by state.

6. A display panel inspection method using a display panel inspection apparatus comprising: at least one image measurement unit which lights a display panel in response to a test signal and picks up the image of the lighted display panel so as to obtain image measurement data; at least one data accumulating unit for accumulating the image measurement data of a plurality of display panels as data corresponding to each display panel; and at least one data processing unit which respectively reads out the image measurement data accumulated in the data accumulating unit and performs image processing so as to judge the quality of each display panel, said method comprising:
an image measurement step of supplying display panel acting as measurement object to the at least one image measurement unit, outputting the image measurement data to the at least one data accumulating unit, discharging a measured display panel and supplying a next display panel acting as a measurement object; and
a data processing step of sorting said image measurement data outputted from the at least one data accumulating unit and corresponding to each display panel to a plurality of data processing units in their stand-by state, and performing said image processing.

7. The display panel inspection method according to claim 6, wherein each processing of the image measurement step and each processing of the data processing step with respect to a plurality of display panels are carried out in parallel.

8. The display panel inspection method according to claim 6, wherein the number of the data processing units is set in accordance with the processing time of the data processing step.

9. The display panel inspection apparatus according to claim 2, further comprising panel supply means for supplying display panel acting as measurement object to the at least one image measurement unit, and panel stocking means for stocking measured display panel discharged from the at least one image measurement unit,
wherein the image measurement unit detects an end of a process of obtaining image measurement data with respect to a display panel set in a predetermined position, and outputs a display panel discharge signal.

10. The display panel inspection apparatus according to claim 9, wherein the image measurement unit detects that a measured display panel has been discharged and outputs a display panel supply signal to the panel supply means.

11. The display panel inspection apparatus according to claim 2,
wherein said apparatus comprises a plurality of data processing units,
wherein the at least one data accumulating unit operates to sort image measurement data corresponding to each display panel to the plurality of data processing units in their stand-by state.

12. The display panel inspection apparatus according to claim 3,
wherein said apparatus comprises a plurality of data processing units,
wherein the at least one data accumulating unit operates to sort image measurement data corresponding to each display panel to the plurality of data processing units in their stand-by state.

13. The display panel inspection apparatus according to claim 9,
wherein said apparatus comprises a plurality of data processing units,
wherein the at least one data accumulating unit operates to sort image measurement data corresponding to each display panel to the plurality of data processing units in their stand-by state.

14. The display panel inspection apparatus according to claim 4,
wherein said apparatus comprises a plurality of data processing units,
wherein the at least one data accumulating unit operates to sort image measurement data corresponding to each display panel to the plurality of data processing units in their stand-by state.

15. The display panel inspection apparatus according to claim 10,
wherein said apparatus comprises a plurality of data processing units,
wherein the at least one data accumulating unit operates to sort image measurement data corresponding to each display panel to the plurality of data processing units in their stand-by state.

16. The display panel inspection method according to claim 7, wherein the number of the data processing units is set in accordance with the processing time of the data processing step.
